(19) United States
(12) Patent Application Publication
(10) Pub. No.: US 2016/0334475 A1
(43) Pub. Date: Nov. 17, 2016

(54) GAS CELL AND MAGNETIC FIELD MEASURING APPARATUS

(71) Applicant: Seiko Epson Corporation, Tokyo (JP)

(72) Inventor: Hitoshi UENO, Fujimi (JP)

(21) Appl. No.: 15/219,559

(22) Filed: Jul. 26, 2016

Related U.S. Application Data
(62) Division of application No. 13/767,186, filed on Feb. 14, 2013.

(30) Foreign Application Priority Data
Feb. 17, 2012 (JP) 2012-032708

(51) Int. Cl. G01R 33/032

(52) U.S. Cl. CPC G01R 33/032

(57) ABSTRACT

A magnetic field measuring apparatus comprises a gas cell, an irradiation unit and a detection unit. The gas cell includes walls forming a closed space, a carbon film on the inner surfaces of the walls, and atoms that are enclosed in the closed space. The irradiation unit applies radiation to the gas cell so as to excite the atoms. The detection unit detects a rotation angle of a polarization plane of the radiation transmitted through the gas cell.

### CROSS-REFERENCE TO RELATED APPLICATIONS

This is a divisional patent application of U.S. application Ser. No. 13/767,186, filed Feb. 14, 2013, which claims priority to Japanese Patent Application No. 2012-032708, filed Feb. 17, 2012. Both applications are expressly incorporated by reference herein in their entireties.

### BACKGROUND

1. Technical Field

The present invention relates to a technology of measuring a magnetic field generated from a living body.

2. Related Art

Technologies of measuring weak magnetic fields generated from hearts and brains have been known. For example, Patent Document 1 (JP-A-2009-236599) discloses an optical pumping magnetometer that measures a magnetic field using pump light and probe light. Non-patent Document 1 (M. A. Bouchiat and J. Brossel, “Relaxation of Optically Pumped Rb Atoms on Paraffin-Coated Walls, “Physical review 147 41, Jul. 8, 1966, pp. 41-54) and Non-patent Document 2 (M. V. Balabas et al., “Polarized alkali vapor with minute-long transverse spin-relaxation time, “Physical review letters 105, 070801, May 11, 2010, pp. 1-5) disclose technologies of coating inner walls of a cell using an organic compound such as alkane or alkene.

In an optical pumping magnetic sensor, a gas cell in which atoms are enclosed is used. When the temperature within the gas cell is raised, the saturated vapor pressure of the atoms becomes higher and the sensitivity is improved. However, in the case where the inner walls of the gas cell are coated using an organic compound such as alkane or alkene like in Non-patent Document 1 and Non-patent Document 2, when the temperature within the gas cell is raised, the spin relaxation time of the atoms becomes shorter due to the temperature characteristics of the coating material. Accordingly, there has been no choice but to set the temperature within the gas cell lower.

### SUMMARY

An advantage of some aspects of the invention is to improve sensitivity of a gas cell.

An aspect of the invention is directed to a gas cell including wall surfaces forming a closed space, a carbon film formed on inner walls of the wall surfaces, and atoms enclosed in the closed space, excited by light, and spin-polarized.

According to the configuration, the sensitivity of the gas cell may be improved.

The carbon film may include diamond-like carbon.

According to this configuration, the property of the carbon film may be finely adjusted by changing a deposition condition.

A surface of the carbon film may be terminated by hydrogen or deuterium.

According to this configuration, absorption energy of the carbon film to the atoms may be reduced.

Another aspect of the invention is directed to a magnetic field measuring apparatus including the above described gas cell, an irradiation unit that applies light to the gas cell, and a detection unit that detects a rotation angle of a polarization plane of the light transmitted through the gas cell.

According to this configuration, the sensitivity of the gas cell may be improved.

The magnetic field measuring apparatus may further include a heating unit that heats the gas cell to a predetermined temperature lower than an upper temperature limit of the carbon film.

According to this configuration, the sensitivity of the gas cell may be improved.

### BRIEF DESCRIPTION OF THE DRAWINGS

The invention will be described with reference to the accompanying drawings, wherein like numbers reference like elements.

FIG. 1 shows a configuration of a magnetic field measuring apparatus according to an embodiment.

FIG. 2 is a flowchart showing a manufacturing process of a gas cell.

FIG. 3 shows classification of diamond-like carbon films.

FIG. 4 is a perspective view showing the manufactured gas cell.

FIGS. 5A and 5B are diagrams for explanation of an action of a coating film.

FIG. 6 shows a relationship between an output voltage of the magnetic field measuring apparatus and magnetic flux density of a magnetic field.

FIG. 7 shows a configuration of a magnetic field measuring apparatus according to a modified example.

### DESCRIPTION OF EXEMPLARY EMBODIMENTS

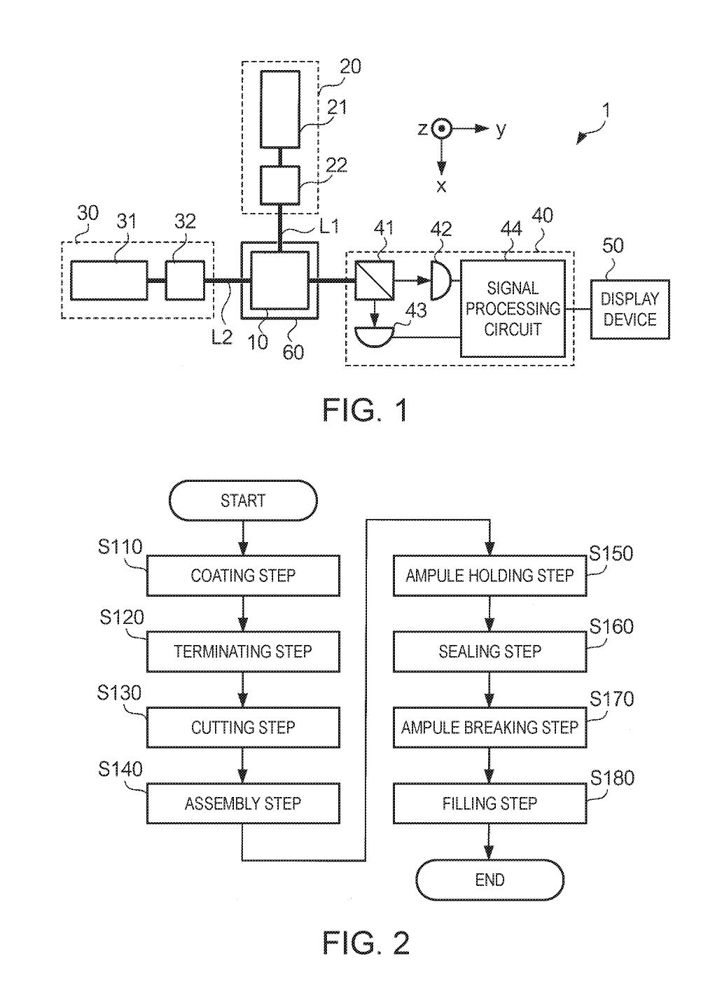

FIG. 1 shows a configuration of a magnetic field measuring apparatus 1 according to an embodiment. The magnetic field measuring apparatus 1 is a magnetic sensor that measures a magnetic field generated from a living body. The magnetic field measuring apparatus 1 is used for a magnetocardiograph that measures a magnetic field generated from a heart (magnetocardiography) and a magnetoencephalograph that measures a magnetic field generated from a brain (magnetoencephalography), for example.

The magnetic field measuring apparatus 1 includes a gas cell 10, a pump light irradiation unit 20, a probe light irradiation unit 30 (an example of an irradiation unit), a detection unit 40, and a display device 50. The gas cell 10 is a cubic container formed using glass. Atoms 11 are enclosed in the gas cell 10. The atoms 11 are alkali metal atoms (cesium or the like), for example. The gas cell 10 is held in a heating unit 60. The heating unit 60 is formed using ceramic with a high coefficient of thermal conductivity. A heat generator such as an electrical heating wire is provided in the heating unit 60. The heating unit 60 heats the gas cell 10 held inside using the heat generator.

The pump light radiation unit 20 has a light source 21 and a polarizer 22. The light source 21 radiates a laser beam. The laser beam radiated from the light source 21 enters the polarizer 22. The polarizer 22 polarizes the entering laser beam and passes pump light L1 having a circularly-polarized light component. The pump light L1 that has passed through the polarizer 22 is applied to the gas cell 10. When the pump light L1 is radiated, the outermost electrons of the atoms 11 within the gas cell 10 are excited and spin polarization occurs. The spin-polarized atoms 11 precess according to the magnetic field.

The probe light irradiation unit 30 has a light source 31 and a polarizer 32. The light source 31 radiates a laser beam. The laser beam radiated from the light source 31 enters the polarizer 32. The polarizer 32 polarizes the entering laser beam and passes probe light L2 having a linearly-polarized light component. The probe light L2 that has passed through the polarizer 32 is transmitted through the gas cell 10. In this regard, the polarization plane of the probe light L2 is rotated by the atoms 11 within the gas cell 10 (Faraday effect). The rotation angle of the polarization plane has a magnitude in response to the intensity of the magnetic field.

The detection unit 40 includes a polarization splitter 41, a first light receiving element 42, a second light receiving element 43, and a signal processing circuit 44. The probe light L2 that has been transmitted through the gas cell 10 enters the polarization splitter 41. The polarization splitter 41 splits the entering probe light L2 into a P-polarized light component and an S-polarized light component. The P-polarized light component split by the polarization splitter 41 enters the first light receiving element 42. The first light receiving element 42 receives the P-polarized light component and outputs an electric signal in response to the received P-polarized light component. On the other hand, the S-polarized light component split by the polarization splitter enters the second light receiving element 43. The second light receiving element 43 receives the S-polarized light component and outputs an electric signal in response to the received S-polarized light component. The electric signals output from the first light receiving element 42 and the second light receiving element 43 are input to the signal processing circuit 44. The signal processing circuit 44 detects the rotation angle of the polarization plane of the probe light L2 based on the input electric signals. Thereby, a magnetic field in a z direction orthogonal to the irradiation direction of the pump light L1 (x direction) and the radiation direction of the probe light L2 (y direction) is measured. The display device 50 is a liquid crystal display, for example. The display device 50 displays a measurement result of the magnetic field.

FIG. 2 is a flowchart showing a manufacturing process of the gas cell 10. At a coating step of step S110, a coating film 13 is formed on a glass plate. The coating film 13 is a diamond-like carbon film formed using a diamond-like carbon. The diamond-like carbon film is a film having an amorphous structure in which carbon and hydrogen of SP³ bonds of diamond and SP² bonds of graphite are mixed. The diamond-like carbon film has a lower deposition temperature and may be formed on the glass plate.

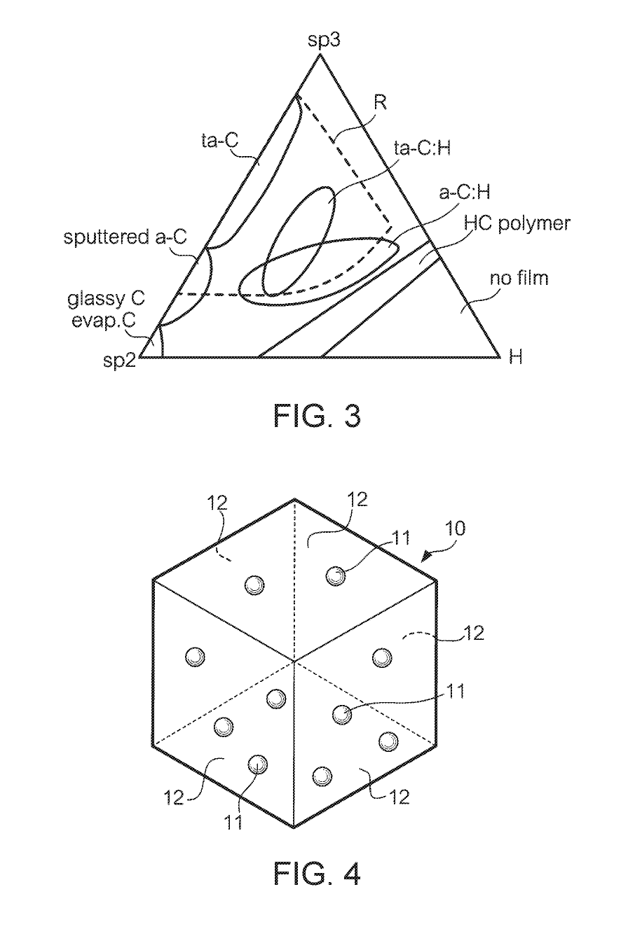

FIG. 3 shows classification of diamond-like carbon films. In FIG. 3, the upper apex indicates diamond, the lower left apex indicates graphite, and the lower right apex indicates hydrogen. The diamond-like carbon film includes at least one of tetrahedral amorphous carbon (ta-C), sputtered amorphous carbon (sputtered a-C), hydrogenated amorphous carbon (a-C:H), and hydrogenated tetrahedral amorphous carbon (ta-C:H) in region R shown in FIG. 3, for example.

The property of the diamond-like carbon film is determined by a ratio of SP³ bonds and SP² bonds and the hydrogen content. For example, when the ratio of SP³ bonds is larger, the property of the diamond-like carbon film becomes closer to the property of diamond. In contrast, when the ratio of SP² bonds is larger, the property of the diamond-like carbon film becomes closer to the property of graphite. The coating film 13 is used for suppressing the relaxation of the spin polarization of the atoms 11. Therefore, it is preferable that the diamond-like carbon film having an optimal property for suppressing the relaxation of the spin polarization of the atoms 11 is selected for the coating film 13.

The diamond-like carbon film has the ratio of SP³ bonds and SP² bonds and the hydrogen content changed depending on the deposition condition. The deposition condition includes a deposition method, a substrate temperature, and a raw material, for example. In the plasma CVD (Chemical Vapor Deposition) method, for example, a film with the higher hydrogen content may be formed. In the plasma CVD method, for example, a diamond-like carbon film including the hydrogenated amorphous carbon (a-C:H) or the hydrogenated tetrahedral amorphous carbon (ta-C:H) is formed. In the laser ablation method, a film with the lower hydrogen content and the larger number of SP³ bond components is formed. In the laser ablation method, for example, a diamond-like carbon film including the tetrahedral amorphous carbon (ta-C) is formed. Note that, in the laser ablation method, the hydrogen content can be increased by changing the other deposition condition than the deposition method. In this case, the SP³ bond components are also slightly increased. In the sputtering method, a diamond-like carbon film in which the hydrogen content is smaller than that of the diamond-like carbon film formed by the laser ablation method and dangling bonds are easily produced on the surface may be formed. In the sputtering method, for example, a diamond-like carbon film including the sputtered amorphous carbon (sputtered a-C) is formed.

As the deposition method of the diamond-like carbon film, in addition to the above described plasma CVD method, laser ablation method, and sputtering method, the arc ion plating method, the ion vapor deposition method, the ion beam method, the thermal CVD method, and the photo CVD method may be used. The deposition condition of the diamond-like carbon film may be determined according to the property of the diamond-like carbon film to be deposited.

At a terminating step of step S120, the surface of the coating film 13 is terminated using deuterium. For example, plasma treatment is performed on the surface of the coating film 13 in an atmosphere of deuterium gas. Thereby, the dangling bonds on the surface of the coating film 13 are terminated by the deuterium. At a cutting step of step S130, the glass plate is cut. Specifically, the glass plate is cut and six members 12 forming an upper wall surface, a lower wall surface, and side wall surfaces of the gas cell 10 (an example of wall surfaces) are cut off. At an assembly step of step S140, the six members 12 are assembled. In this regard, the six members 12 are assembled so that the surfaces on which the coating film 13 has been respectively formed may be inside. The adjacent members 12 are bonded using a sealing material such as low-melting-point glass. Thereby, the wall surfaces of the gas cell 10 are formed. Note that, at this time, the member 12 forming the upper wall surface of the gas cell 10 is not bonded.

At an ampule holding step of step S150, an ampule is held within the gas cell 10. In the ampule, for example, an alkali metal solid is enclosed. The ampule is put inside from the upper surface of the gas cell 10. At a sealing step of step S160, the gas cell 10 is sealed. Specifically, the member 12 forming the upper wall surface of the gas cell 10 is bonded using a sealing material such as low-melting-point glass. At an ampule breaking step of step S170, the ampule within the gas cell 10 is broken. Specifically, a laser beam is applied to the ampule, and a hole is pierced in the ampule. At a filling step of step S180, the gas cell 10 is filled with an alkali metal gas. Specifically, the gas cell 10 is heated by the heating unit 60. Thereby, the alkali metal enclosed in the ampule is gasified and the alkali metal gas is emitted from the ampule.

FIG. 4 is a perspective view showing the manufactured gas cell 10. In the gas cell 10, a closed space is formed by the six members 12. In the closed space, the atoms 11 of the gasified alkali metal are enclosed. On the inner walls of the gas cell 10, the coating film 13 including the diamond-like carbon is formed.

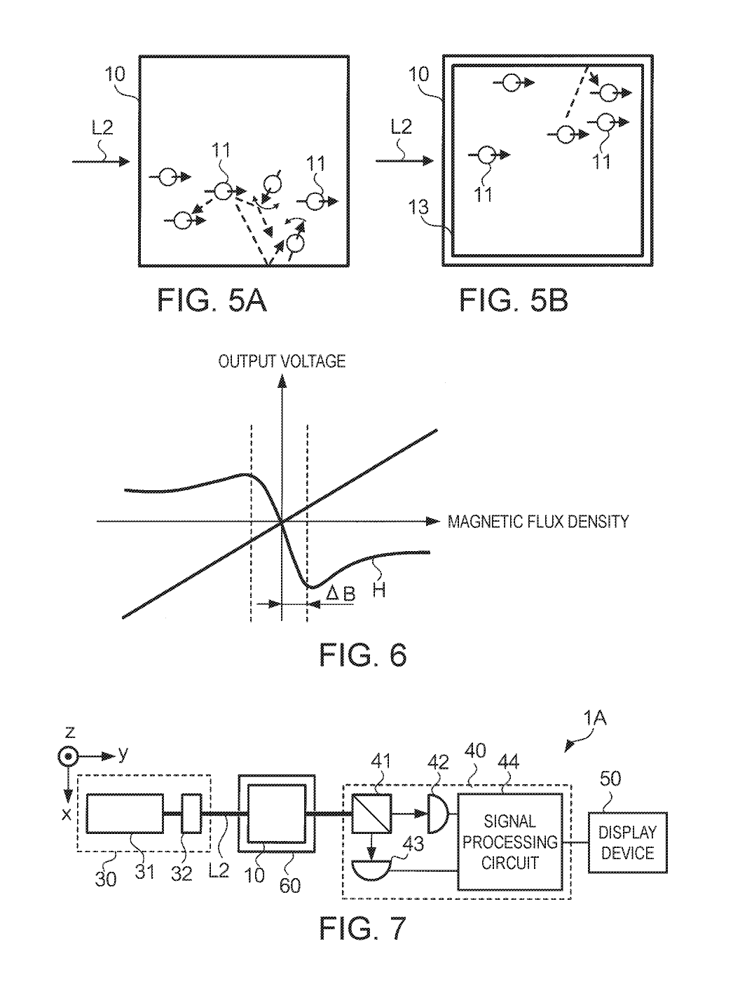

FIGS. 5A and 5B are diagrams for explanation of an action of the coating film 13. When the coating film 13 is not formed on the inner walls of the gas cell 10, as shown in FIG. 5A, the spin-polarized atoms 11 directly collide with the glass surfaces of the gas cell 10, and the spin polarization is easily lost. On the other hand, when the coating film 13 is formed on the inner walls of the gas cell 10, the coating film 13 serves to suppress relaxation of the spin polarization. Accordingly, as shown in FIG. 5B, even when the spin-polarized atoms 11 collide with the inner walls of the gas cell 10, the spin polarization is maintained. Thereby, the spin relaxation time T of the atoms 11 increases.

Further, the coating film 13 includes the diamond-like carbon of carbon and hydrogen. Accordingly, the interaction between the coating film 13 and the electron spin of the atoms 11 may be suppressed. Further, the surface of the coating film 13 is terminated by deuterium and the interaction may be further suppressed, and the absorption energy of the coating film 13 with respect to the atoms 11 decreases and the time of the above described interaction may be reduced.

FIG. 6 shows a relationship between an output voltage of the magnetic field measuring apparatus 1 and magnetic flux density of the magnetic field. In FIG. 6, the vertical axis indicates the output voltage of the magnetic field measuring apparatus 1 and the horizontal axis indicates the magnetic flux density of the magnetic field. An output voltage waveform of the magnetic field measuring apparatus 1 is shown by waveform H. Given that the spin relaxation time of the atoms 11 is T and a gyromagnetic ratio is γ, a half bandwidth ΔB of the peak of the waveform H is expressed by the following equation (1).

ΔB=1/Tγ Eq. (1)

The half bandwidth ΔB has an effect on the sensitivity of the magnetic field measuring apparatus 1. Specifically, the smaller the half bandwidth ΔB, the higher the sensitivity of the gas cell 10. As described above, when the coating film 13 is formed on the inner walls of the gas cell 10, the spin relaxation time T of the atoms 11 increases. In this case, the half bandwidth ΔB is smaller according to the above described equation (1), and the sensitivity of the gas cell 10 is improved.

Further, the diamond-like carbon forming the coating film 13 has an upper temperature limit of 400 degrees, for example. Accordingly, the temperature within the gas cell 10 may be made higher than that in related art. In this case, the saturated vapor pressure of the atoms 11 becomes higher and the sensitivity of the gas cell 10 is improved. For example, it is preferable that the temperature within the gas cell 10 is set to a relatively high temperature in a lower temperature range than the upper temperature limit of the coating film 13 (for example, 400 degrees). In this case, the heating unit 60 heats the gas cell 10 to a predetermined temperature lower than the upper temperature limit of the coating film 13.

In the case where the coating film 13 includes paraffin, when the temperature within the gas cell 10 becomes 60 to 80 degrees, for example, the spin relaxation time of the atoms 11 rapidly decreases. Further, in the case where the coating film 13 includes an alkene compound, when the temperature within the gas cell 10 becomes 33 degrees or higher, for example, the spin relaxation time of the atoms 11 rapidly decreases. In the case where the coating film 13 includes diamond-like carbon, when the temperature within the gas cell 10 may be raised to a temperature of 60 to 80 degrees or higher or a temperature of 33 degrees or higher.

Furthermore, the property of the diamond-like carbon forming the coating film 13 may be finely adjusted by changing the deposition condition. Thereby, the coating film 13 having an optimal property for suppressing the relaxation of the spin state of the atoms 11 may be deposited.

The invention is not limited to the above described embodiment, but may be modified as below. Further, the following modified examples may be combined with one another.

### (1) Modified Example 1

The material forming the coating film 13 is not limited to the diamond-like carbon. It is only necessary that the coating film 13 is a carbon film formed by a material including a carbon-based material. For example, the coating film 13 may include diamond or graphite. Note that, it is preferable that the coating film 13 may be deposited on the surface of the material of the gas cell 10. Further, it is preferable that the coating film 13 transmits the pump light L1 and the probe light L2.

### (2) Modified Example 2

The material for terminating the surface of the coating film 13 is not limited to deuterium. For example, the surface of the coating film 13 may be terminated by hydrogen. Also, in this case, the absorption energy of the coating film 13 with respect to the atoms 11 decreases and the time of the above described interaction may be reduced.

### (3) Modified Example 3

The magnetic field measuring apparatus 1 is not limited to the dual-beam magnetic sensor using the pump light and the probe light. For example, the magnetic field measuring apparatus 1 may be a single-beam magnetic sensor using single light as both the pump light and the probe light.

FIG. 7 shows a configuration of single-beam magnetic field measuring apparatus 1A. The magnetic field measuring apparatus 1A includes the other configuration than the pump light radiation unit 20 of the configuration of the above described magnetic field measuring apparatus 1. In this case, in the magnetic field measuring apparatus 1A, a magnetic field in the y direction the same as the radiation direction of the probe light L2 is measured.

### (4) Modified Example 4

A plurality of the gas cells 10 may be provided. Generally, when the plural gas cells 10 are used, formation of the coating film 13 easily varies among the gas cells 10. However, the carbon film such as a diamond-like carbon film has high reproducibility of deposition. Therefore, even when the plural gas cells 10 are used, variations in the formation of the coating film 13 among the gas cells 10 become smaller.

### (5) Modified Example 5

The manufacturing method of the gas cell 10 is not limited to the method explained in the embodiment. For example, the lower wall surface and the side wall surfaces of the gas cell 10 may be integrally formed by glass shaping. Further, after the assembly of the gas cell 10, the coating step and the terminating step may be performed. In this case, the coating film 13 may be formed on the inner walls of the gas cell 10 by application of the method disclosed in JP-A-2004-115853, for example.

### (6) Modified Example 6

The material of the gas cell 10 is not limited to glass. It is only necessary that the gas cell 10 is formed using a material with higher light transmissivity. For example, the gas cell 10 maybe formed using plastic. The shape of the gas cell 10 is not limited to the cube. For example, the gas cell 10 has a shape with a curved surface in a part of a rectangular parallelepiped, a polyhedron, a globe, a cylinder, or the like.

### (7) Modified Example 7

The atoms 11 may be introduced into the gas cell 10 in any state of solid, liquid, or gas. It is only necessary that the atoms 11 are gasified at least at measurement and not necessary that the atoms are constantly in the gas state.

### (8) Modified Example 8

The apparatus in which the gas cell 10 is used is not limited to the magnetic field measuring apparatus 1. The gas cell 10 can be used in apparatus using a principle of light pumping. For example, the gas cell 10 may be used for an atomic oscillator.

What is claimed is:

1. A magnetic field measuring apparatus comprising:
a gas cell including:
walls forming a closed space, the walls having inner and outer surfaces;
a carbon film on the inner surfaces of the walls; and
atoms enclosed in the closed space;
an irradiation unit optically upstream of the gas cell and configured to apply radiation to the gas cell so as to excite the atoms; and
a detection unit optically downstream of the gas cell and configured to detect a rotation angle of a polarization plane of the radiation transmitted through the gas cell.

2. The magnetic field measuring apparatus according to claim 1,
wherein the carbon film includes diamond-like carbon.

3. The magnetic field measuring apparatus according to claim 1,
wherein a surface of the carbon film is terminated by hydrogen or deuterium.

4. The magnetic field measuring apparatus according to claim 1, further comprising:
a heater operatively associated with the gas cell and configured to heat the gas cell to a predetermined temperature, the predetermined temperature being lower than an upper temperature limit of the carbon film.

5. The magnetic field measuring apparatus according to claim 2, further comprising:
a heater operatively associated with the gas cell and configured to heat the gas cell to a predetermined temperature, the predetermined temperature being lower than an upper temperature limit of the carbon film.

6. The magnetic field measuring apparatus according to claim 3, further comprising:
a heater operatively associated with the gas cell and configured to heat the gas cell to a predetermined temperature, the predetermined temperature being lower than an upper temperature limit of the carbon film.
